(19) United States
(12) Patent Application Publication
(10) Pub. No.: US 2025/0282019 A1
(43) Pub. Date: Sep. 11, 2025

(54) PROCESSING APPARATUS AND WAFER PROCESSING METHOD

(71) Applicant: DISCO CORORATION, Tokyo (JP)

(72) Inventor: Nobuyuki FUKUSHI, Tokyo (JP)

(21) Appl. No.: 19/056,918

(22) Filed: Feb. 19, 2025

(30) Foreign Application Priority Data
Mar. 5, 2024 (JP) 2024-032860
Nov. 19, 2024 (JP) 2024-201531

(51) Int. Cl. B24B 37/005; H01L 21/67; H01L 21/683

(52) U.S. Cl. CPC B24B 37/005; H01L 21/67259; H01L 21/6838

(57) ABSTRACT

A processing apparatus includes a cassette stage for mounting a cassette thereon, a chuck table to suction-hold a wafer, a processing unit to process the wafer that is held on the chuck table, a processing table that is used to perform a predetermined processing on a wafer, a robot equipped with a robot hand that has a wafer presence sensor to detect a presence or absence of a wafer and holds a wafer to unload or load the wafer from or into the cassette mounted on the cassette stage, and a controller that uses the wafer presence sensor of the robot hand to detect whether a wafer is present on the processing table.

### CROSS-REFERENCE TO RELATED APPLICATION

This application claims priority from Japanese Patent Application No. 2024-32860 filed with the Japan Patent Office on Mar. 5, 2024, and from Japanese Patent Application No. 2024-201531 filed with the Japan Patent Office on Nov. 19, 2024, the entire contents of both of which are hereby incorporated.

### BACKGROUND ART

### 1. Technical Field

The present invention relates to a processing apparatus and a wafer processing method.

### 2. Related Art

As disclosed in JP 2021-126744A and JP 2021-132180A, in a processing apparatus such as a grinding apparatus for grinding a wafer, a wafer is transferred from a cassette mounted on a cassette stage to a chuck table, where the wafer held on the chuck table is ground by a grinding stones. Subsequently, the wafer is transferred from the chuck table to a spinner table of a spinner cleaning unit, cleaned on the spinner table, and then stored in a cassette.

### SUMMARY

When holding and cleaning a wafer on a spinner table, if the wafer is warped, the processing apparatus may recognize that the wafer is not held on the spinner table and halt the cleaning operation. That is, although the wafer is present on the spinner table, the processing apparatus may occasionally determine that no wafer is present on the spinner table.

If a continuous processing proceeds in this state, a next wafer is mounted on top of the wafer already on the spinner table, leading to potential separation and damage of the overlapping wafer while cleaning in a spinner cleaning unit.

Accordingly, a purpose of the present invention is to accurately detect the presence or absence of a wafer on a table such as a spinner table.

A processing apparatus according to one aspect of the present invention (the present processing apparatus) includes a cassette stage for mounting a cassette thereon, a chuck table to suction-hold a wafer, a processing unit to process the wafer that is held on the chuck table, a processing table that is used to perform a predetermined processing on a wafer, a robot equipped with a robot hand that has a wafer presence sensor to detect a presence or absence of a wafer and holds a wafer to unload or load the wafer from or into the cassette mounted on the cassette stage, and a controller that uses the wafer presence sensor of the robot hand to detect whether a wafer is present on the processing table.

In the present processing apparatus, the processing table may be the spinner table that suction-holds a wafer to perform the cleaning process on the wafer. This specific embodiment of the present processing apparatus is referred to as a first processing apparatus.

In the first processing apparatus, the controller may use the wafer presence sensor of the robot hand to detect the presence or absence of a wafer on the spinner table while relatively moving the spinner table and the robot hand positioned above the spinner table in a horizontal direction.

The first processing apparatus may further include a pressure sensor that measures a pressure value in a suction pipe connecting the spinner table and a suction source. In this case, when the spinner table suction-holds the wafer, if the measurement of the pressure sensor does not fall no more than a predetermined threshold, the controller may use the wafer presence sensor of the robot hand to detect the presence or absence of a wafer on the spinner table.

In the present processing apparatus, the processing table may be a positioning table for positioning a wafer to be held on the chuck table. This specific embodiment of the present processing apparatus is referred to as a second processing apparatus.

In the second processing apparatus, the controller may use the wafer presence sensor of the robot hand to detect the presence or absence of a wafer on the positioning table while relatively moving the positioning table and the robot hand, which is positioned above the positioning table in a horizontal direction.

The second processing apparatus may further include a pressure sensor that measures a pressure value in a suction pipe connecting the positioning table and a suction source. In this case, when the positioning table suction-holds the wafer, if the measurement of the pressure sensor does not fall no more than the predetermined threshold, the controller may use the wafer presence sensor of the robot hand to detect the presence or absence of a wafer on the positioning table.

A first wafer processing method according to one aspect of the present invention is the wafer processing method for processing the wafer using the first processing apparatus, which includes holding the wafer on the chuck table, processing the wafer with the processing unit, holding the processed wafer on the spinner table and cleaning the wafer, and detecting the presence or absence of a wafer on the spinner table using the wafer presence sensor of the robot hand at a predetermined timing before the cleaning of the wafer, where during the detection of the presence or absence of a wafer on the spinner table, if a wafer is detected to be absent from the spinner table, cleaning of the wafer is performed, while during the detection of the presence or absence of a wafer, if a wafer is detected to be present on the spinner table, a notification unit of the processing apparatus notifies an operator that a wafer is present on the spinner table.

A second wafer processing method according to another aspect of the present invention is a wafer processing method for processing the wafer using the second processing apparatus, which includes unloading a wafer from the cassette and holding the wafer on the positioning table to perform positioning of the wafer, holding the positioned wafer on the chuck table, processing the wafer with the processing unit; and detecting the presence or absence of a wafer on the positioning table using the wafer presence sensor of the robot hand at a predetermined timing before the positioning of the wafer, where during the detection of the presence or absence of a wafer on the positioning table, if a wafer is detected to be absent from the positioning table, positioning of the wafer is performed, while during the detection of the presence or absence of a wafer, if a wafer is detected to be present on the positioning table, a notification unit of the processing apparatus notifies an operator that a wafer is present on the positioning table.

In the present processing apparatus and the first and second wafer processing methods, the wafer presence sensor of the robot hand detects the presence or absence of a wafer on the processing table (for example, the spinner table or the positioning table). As a result, the presence or absence of the wafer on the processing table can clearly be detected. Consequently, for example, situations where an unsuitable wafer remains on the processing table and an overlapping wafer is mounted thereon causing damage to the wafer, can be effectively suppressed. Furthermore, the need for an operator to visually confirm the presence or absence of the wafer on the processing table is eliminated, thereby improving operational efficiency.

### BRIEF DESCRIPTION OF THE DRAWINGS

FIG. 1 is a perspective view illustrating a structure of a grinding apparatus.

FIG. 2 is a cross-sectional view illustrating a configuration of a spinner table.

FIG. 3 is a cross-sectional view illustrating a configuration of a positioning table.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

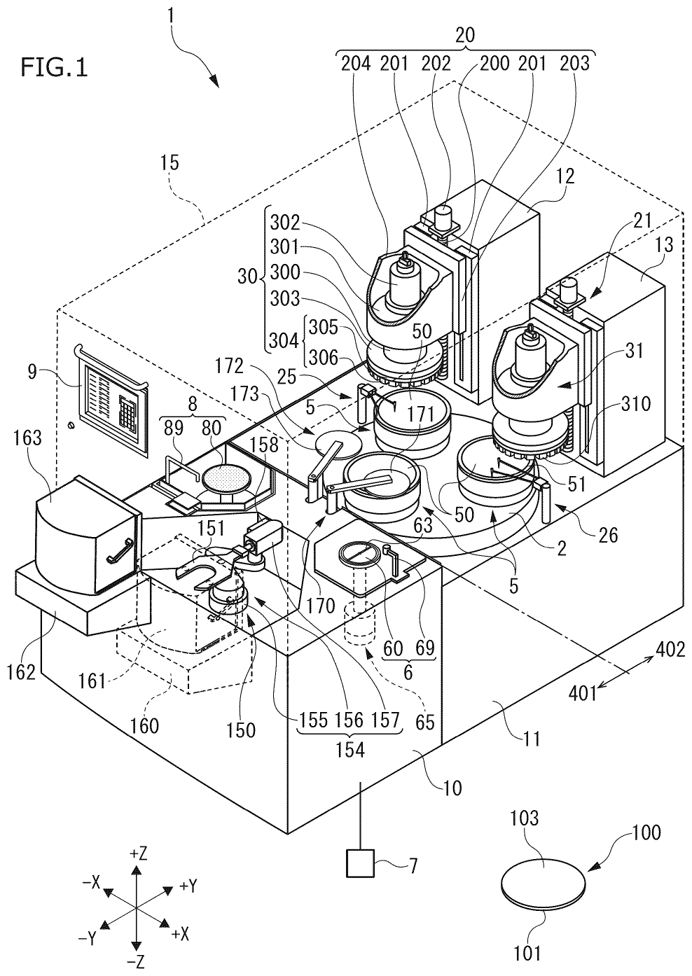

A grinding apparatus 1 shown in FIG. 1 is an example of a processing apparatus. The grinding apparatus 1 grinds a wafer 100 held on a chuck table 5 using a rough grinding mechanism 30 and a finish grinding mechanism 31.

The wafer 100 shown in FIG. 1 is an example of a workpiece and may be, for instance, a circular semiconductor wafer. On a surface 101 of the wafer 100, which faces downward in FIG. 1, a device (not shown) is formed. A back surface 103 of the wafer 100 serves as a processed surface subjected to grinding.

The grinding apparatus 1 includes a first apparatus base 10 and a second apparatus base 11 disposed behind the first apparatus base 10 (+Y direction side). An area above the first apparatus base 10 serves as a loading and unloading area 401 for the wafer 100, where the wafer 100 is loaded and unloaded. A processing area 402 is positioned above the second apparatus base 11. In a processing area 402, the rough grinding mechanism 30 and the finish grinding mechanism 31 process the wafer 100 that is held on the chuck table 5.

A first cassette stage 160 and a second cassette stage 162 for mounting the cassettes are provided at a front side (−Y direction side) of the first apparatus base 10. A first cassette 161 and a second cassette 163, each housing the wafer 100, are mounted on the first cassette stage 160 and the second cassette stage 162, respectively.

The first cassette 161 and the second cassette 163 are provided with multiple shelves inside, with each shelf accommodating a single wafer 100.

The openings (not shown in the figures) of the first cassette 161 and the second cassette 163 face the +Y direction. A robot 150 is positioned on the +Y direction side of these openings.

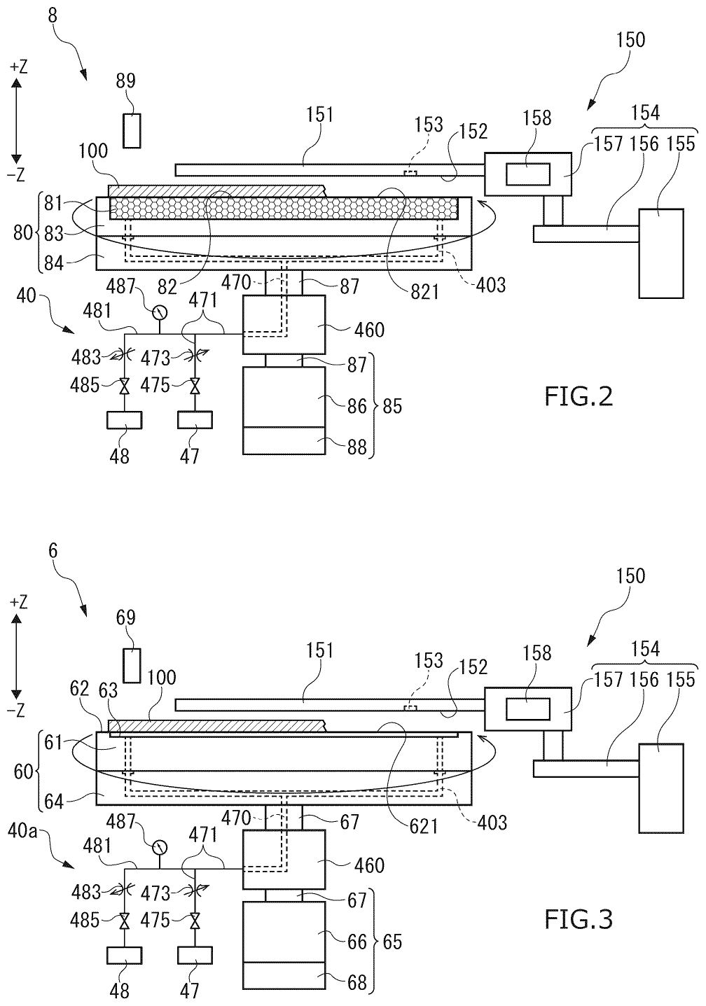

The robot 150 is equipped with a robot hand 151 that holds the wafer 100 for unloading or loading the wafer 100 from or into the first cassette 161 and the second cassette 163. The robot hand 151 features a U-shaped plate structure and is equipped with a suction surface 152 (see FIG. 2) on one surface, allowing to hold the wafer 100 through suction.

The robot hand 151 is further equipped with a wafer presence sensor 153 on the suction surface 152 to detect the presence or absence of the wafer 100, as well as a controller 158 to detect the presence or absence of the wafer 100. In this embodiment, the wafer presence sensor 153 is used, for example, to detect whether the wafer 100 is present at a position opposite the suction surface 152.

For example, the wafer presence sensor 153 includes a light emitter and a light receiver, and the light emitter emits light toward the predetermined position opposite the suction surface 152, while the light receiver receives the reflected light that the light emitter emits. The controller 158 determines the presence or absence of the wafer 100 at the predetermined position based on the amount of reflected light received. The controller 158 may also serve as the controller 7 of the grinding apparatus 1.

As shown in FIGS. 1 and 2, the robot 150 includes a drive unit 154 that operates the robot hand 151. The drive unit 154 controls (adjusts) the position of the robot hand 151. Specifically, the drive unit 154 is equipped with a vertical movement mechanism 155, a horizontal movement mechanism 156, and an inversion mechanism 157.

The vertical movement mechanism 155 moves the robot hand 151 vertically along the Z-axis direction. The horizontal movement mechanism 156 moves the robot hand 151 horizontally. The inversion mechanism 157 flips the robot hand 151 to position the suction surface 152 either upward or downward.

With this configuration, the robot 150 loads the processed wafers 100, held by the robot hand 151, to either the first cassette 161 or the second cassette 163 shown in FIG. 1. Additionally, the robot 150 uses the robot hand 151 to unload the unprocessed wafer 100 housed in the first cassette 161 or the second cassette 163 and to mount the wafer 100 onto the positioning table 60 of the positioning mechanism 6.

The positioning mechanism 6 is used to position the wafer 100 (for example, detecting the center position) unloaded from the first cassette 161 or the second casse tte 163 and is disposed adjacent to the robot 150. The positioning mechanism 6 includes the positioning table 60 that holds and rotates the wafer 100 and a center position detection unit 69 equipped with a camera.

The positioning table 60 is an example of a processing table used for performing the predetermined processing (positioning of the wafer 100) on the wafer 100. The positioning table 60 is a table to position the wafer 100 to be held on the chuck table 5. The positioning table 60 is communicated with a suction source 48 (see FIG. 3), thereby enabling to suction-hold the wafer 100 mounted on the positioning table 60. The center position detection unit 69 detects the center of the wafer 100 suction-held on the positioning table 60.

In the positioning mechanism 6, the positioning table 60, while suction-holding the wafer 100, rotates at a low rotational speed, and the center position detection unit 69 captures images of multiple locations (for example, three locations) along the outer edge of the wafer 100. The center position detection unit 69 detects the center position of the wafer 100 by performing geometric calculations based on the coordinates of the captured locations.

The positioning mechanism 6 may also include a mechanism (for example, a centering pin) for aligning the wafer 100 mounted on the positioning table 60 to the predetermined position where the center of the positioning table 60 coincides with the center of the wafer 100.

A loading mechanism 170 is installed adjacent to the positioning mechanism 6. The loading mechanism 170 is an example of a transport mechanism that unloads or loads the wafer 100 from or onto the chuck table 5. The loading mechanism 170 loads the wafer 100 held by the positioning mechanism 6 onto the chuck table 5.

The loading mechanism 170 includes a transport pad 171 that suction-holds the back surface 103 of the wafer 100. The loading mechanism 170 uses the transport pad 171 to suction-hold the wafer 100, which is held on the positioning table 60, to transfer the wafer 100 onto the chuck table 5, which is located near the positioning mechanism 6 within the processing area 402, and to mount the wafer 100 on the holding surface 50 such that the center of the holding surface 50 aligns approximately with the center of the wafer 100.

The chuck table 5 is a member that suction-holds the wafer 100 and has a holding surface 50. The holding surface 50 is communicated with a suction source (not shown in the figures), enabling to suction-hold the wafer 100. The chuck table 5 holds the wafer 100 on the holding surface 50 and, in this state, is capable of rotating around a central axis that extends in the Z-axis direction through the center of the holding surface 50.

In this embodiment, three chuck tables 5 are arranged on the upper surface of the turntable 2 arranged on the second apparatus base 11 at equal intervals on a circle centered on a turntable 2. At the center of the turntable 2, a rotation shaft (not shown in the figures) for rotating the turntable 2 is arranged. The turntable 2 can rotate around the central axis, which extends in the Z-axis direction, via this rotational shaft. The rotation of the turntable 2 enables the three chuck tables 5 to revolve. As a result, the chuck tables 5 can be sequentially positioned near the positioning mechanism 6, beneath the rough grinding mechanism 30, and beneath the finish grinding mechanism 31.

At the rear (+Y direction side) of the second apparatus base 11, a first column 12 is installed upright. On the front face of the first column 12, a rough grinding mechanism 30 for rough grinding the wafer 100 and a rough grinding feed mechanism 20 for feeding the rough grinding mechanism 30 are provided. The rough grinding mechanism 30 is an example of a processing unit that processes the wafer 100 held on the chuck table 5, and rough grinds on the wafer 100.

The rough grinding feed mechanism 20 moves the rough grinding mechanism 30 in a direction perpendicular to the holding surface 50. The rough grinding feed mechanism 20 has a pair of guide rails 201 parallel to the Z-axis direction, an elevating table 203 sliding on the guide rails 201, a ball screw 200 parallel to the guide rails 201, a motor 202 for rotationally driving the ball screw 200, and a holder 204 mounted on the front face (surface) of the elevating table 203. The holder 204 holds the rough grinding mechanism 30.

The elevating table 203 is slidably installed on the guide rails 201. A nut portion (not shown in the figures) is fixed to the elevating table 203. The ball screw 200 is screwed into this nut portion. The motor 202 is connected to one end of the ball screw 200.

In the rough grinding feed mechanism 20, the motor 202 rotates the ball screw 200, causing the elevating table 203 to move along the guide rails 201 in the Z-axis direction. Consequently, a holder 204 mounted on the elevating table 203, along with the rough grinding mechanism 30 held by the holder 204, also moves in the Z-axis direction with the elevating table 203. In this manner, the rough grinding feed mechanism 20 feeds the rough grinding mechanism 30 in the Z-axis direction for grinding.

The rough grinding mechanism 30 has a spindle housing 301 fixed to the holder 204, a spindle 300 rotatably held in the spindle housing 301, a spindle motor 302 for rotationally driving the spindle 300, a wheel mount 303 attached to a lower end of the spindle 300, and a grinding wheel 304 detachably connected to a lower surface of the wheel mount 303.

The spindle housing 301 is held by the holder 204 so as to be extending in the Z-axis direction. The spindle 300 extends in the Z-axis direction, perpendicular to the holding surface 50 of the chuck table 5 and is rotatably supported by the spindle housing 301.

The spindle motor 302 is connected to the upper end side of the spindle 300. This spindle motor 302 rotates the spindle 300 around a rotational axis extending in the Z-axis direction.

The wheel mount 303 is formed in a disk shape and is fixed to a tip (lower end) of the spindle 300, rotating in accordance with the rotation of the spindle 300. The wheel mount 303 supports the grinding wheel 304.

The grinding wheel 304 is formed with an outer diameter thereof approximately equal to an outer diameter of the wheel mount 303. The grinding wheel 304 includes an annular wheelbase 305 made of metal. On a lower surface of the wheelbase 305, multiple approximately rectangular rough grinding stones 306 are arranged and fixed in an annular configuration around an entire circumference.

The rough grinding stones 306 are rotated because of the rotation of the spindle 300, and the lower surfaces of the rough grinding stones 306 perform rough grinding on a back surface 103 of the wafer 100 held on the chuck table 5. The rough grinding stones 306 contain relatively large abrasive grains.

Also, in the vicinity of the rough grinding mechanism 30, a first measurement mechanism 25 is arranged. The first measurement mechanism 25 measures a thickness of the wafer 100 held on the chuck table 5 positioned below the rough grinding mechanism 30.

At a rear of the second apparatus base 11, a second column 13 is erected adjacent to the first column 12 along the X-axis direction. On a front face of the second column 13, a finish grinding mechanism 31 for finish grinding the wafer 100 and a finish grinding feed mechanism 21 for feeding the finish grinding mechanism 31 for grinding are arranged. The finish grinding mechanism 31 is an example of a processing unit that processes the wafer 100 held on the chuck table 5, performing finish grinding on the wafer 100.

The finish grinding feed mechanism 21 moves the finish grinding mechanism 31 in a direction perpendicular to the holding surface 50. The finish grinding feed mechanism 21 has the same configuration as the rough grinding feed mechanism 20 and can feed the finish grinding mechanism 31 along the Z-axis direction for grinding.

The finish grinding mechanism 31 has the same configuration as the rough grinding mechanism 30, except that the finish grinding mechanism 31 includes a finish grinding stones 310 instead of the rough grinding stones 306. The finish grinding stones 310 is rotated because of the rotation of the spindle 300, and a lower surface of the finish grinding stones 310 performs finish grinding on the back surface 103 of the wafer 100 held on the chuck table 5. The finish grinding stones 310 is a grinding wheel containing relatively small abrasive grains.

Also, in the vicinity of the finish grinding mechanism 31, a second measurement mechanism 26 is arranged. The second measurement mechanism 26 measures a thickness of the wafer 100 held on the chuck table 5 positioned below the finish grinding mechanism 31.

The wafer 100 after the finish grinding is unloaded by an unloading mechanism 172. The unloading mechanism 172 is an example of a transport mechanism that unloads or loads the wafer 100 from or onto the chuck table 5. The unloading mechanism 172 transfers the wafer 100 held on the chuck table 5 to a spinner cleaning mechanism 8.

The unloading mechanism 172 has a transport pad 173 that suction-holds the back surface 103 of the wafer 100. The unloading mechanism 172 suction-holds the back surface 103 of the finish ground wafer 100 on the chuck table 5 using the transport pad 173. The unloading mechanism 172 then unloads the wafer 100 from the chuck table 5 and transfers the wafer 100 to a spinner table 80 of the single-wafer spinner cleaning mechanism 8.

The spinner cleaning mechanism 8 is a spinner cleaning unit that cleans the wafer 100. The spinner cleaning mechanism 8 includes the spinner table 80 for suction-holding the wafer 100 to be cleaned and a nozzle 89 for spraying cleaning water and dry air toward the spinner table 80.

In the spinner cleaning mechanism 8, the spinner table 80 that holds the wafer 100 rotates, and cleaning water is sprayed onto the wafer 100, performing spinner cleaning of the water 100. Subsequently, drying air is blown onto the wafer 100 to dry the wafer 100.

Here, the configuration of the spinner table 80 will be described. The spinner table 80 is an example of a processing table used for performing the predetermined processing (cleaning of the wafer 100) on the wafer 100. As shown in FIG. 2, the spinner table 80 is a circular plate-shaped table for holding the wafer 100. The spinner table 80 has a circular plate-shaped porous member 81, a frame 83 supporting the porous member 81, and a table base 84 supporting the frame 83. The porous member 81 can be communicated with the suction source 48. The suction force from the suction source 48 is transmitted to a holding surface 82, which is the upper surface of the porous member 81, enabling the spinner table 80 to suction-hold the wafer 100 by the holding surface 82.

The spinner table 80 is also rotatable by a rotation mechanism 85. The rotation mechanism 85 is equipped with a motor 86 serving as a drive source, a shaft 87 of the motor 86, and an encoder 88 for reading the rotational angle of the motor 86.

The shaft 87 is connected to an underside of the spinner table 80 (table base 84) directly below the center of the holding surface 82 and extends vertically to the holding surface 82 of the spinner table 80. The motor 86 rotationally drives the shaft 87, causing the spinner table 80 to rotate around the center of the holding surface 82. Furthermore, the encoder 88 allows the rotational angle of the spinner table 80 to be recognized based on the rotational angle of the motor 86.

The spinner table 80 is connected to a fluid circulation mechanism 40 provided in the grinding apparatus 1. The fluid circulation mechanism 40 is a mechanism designed to supply air to the holding surface 82 of the spinner table 80 or to apply suction force to the holding surface 82.

The fluid circulation mechanism 40 has a table internal flow path 403 provided inside the spinner table 80, an air passage 470 communicating with the table internal flow path 403, a rotary joint 460 connected to the shaft 87, and an air pipe 471 communicating with the air passage 470.

The table internal flow path 403 is arranged within the frame 83 and table base 84 of the spinner table 80 so as to contact the lower surface of the porous member 81. The air passage 470 extends from the table internal flow path 403, passing through the shaft 87 and the rotary joint 460.

The air passage 470 is connected to one end of the air pipe 471 outside the rotary joint 460. The other end of the air pipe 471 is connected to the air supply source 47. The air supply source 47, which is equipped with such as a compressor, is used to supply air to the holding surface 82 of the spinner table 80.

In addition, the air pipe 471 is equipped with an air supply on-off valve 475 and an air regulator 473 in sequence from the air supply source 47 toward the air passage 470. The air supply on-off valve 475 switches the communication state between the air pipe 471 and the air supply source 47. The air regulator 473, for example, is a proportional control valve and is used to adjust the flow rate of air supplied from the air supply source 47 to the holding surface 82 by changing the orifice diameter inside thereof when the air supply on-off valve 475 is open.

Furthermore, the air pipe 471 is communicated with a suction pipe 481. The suction pipe 481 is a pipe that communicates with the holding surface 82 of the spinner table 80 to the suction source 48.

One end of the suction pipe 481 is connected to the air passage 470 via the air pipe 471. The other end of the suction pipe 481 is connected to the suction source 48. The suction source 48, for example, is equipped with such as an ejector mechanism or a vacuum generator and is communicated with the porous member 81 of the spinner table 80 in order to apply suction force to the holding surface 82 that is an upper surface of the porous member 81.

Furthermore, the suction pipe 481 is also equipped with a suction opening and closing valve 485 and a suction flow regulator 483 in sequence from the suction source 48 toward the air passage 470. The suction opening and closing valve 485 switches the communication state between the suction pipe 481 and the suction source 48. The suction flow regulator 483, for example, is a proportional control valve and is used to adjust the suction force transmitted from the suction source 48 to the holding surface 82 of the porous member 81 by changing the orifice diameter inside thereof when the suction opening and closing valve 485 is open.

Also, it should be noted that the air regulator 473 and the suction flow regulator 483 may also be needle valves or gate valves that allow manual adjustment of the orifice diameter.

Additionally, the suction pipe 481 is equipped with a pressure sensor 487. The pressure sensor 487 detects the pressure value in the suction pipe 481. In this embodiment, for example, when the suction opening and closing valve 485 is opened to communicate the holding surface 82 with the suction source 48, if the pressure sensor 487 measures a pressure value in the suction pipe 481 no more than a predetermined threshold, it is determined that the wafer 100 is mounted on the holding surface 82 of the spinner table 80 and that the wafer 100 is being held by the holding surface 82.

The wafer 100, cleaned by the spinner cleaning mechanism 8 having the spinner table 80 with the above-described configuration, is loaded into the first cassette 161 or the second cassette 163 (for example, the cassette from which the wafer 100 was unloaded) by the robot 150 shown in FIG. 1.

As shown in FIG. 1, the grinding apparatus 1 has a housing 15 that covers the first apparatus base 10 and the second apparatus base 11. A touch panel 9 is installed on a side of the housing 15. The touch panel 9 displays various types of information, such as conditions for processing with respect to the grinding apparatus 1. The touch panel 9 is also used for setting various parameters. Accordingly, the touch panel 9 functions as an input member for inputting information and as a display member (notification member) for displaying (notifying) information.

The grinding apparatus 1 also includes the controller 7 therein for controlling the grinding apparatus 1. The controller 7 is equipped with such as CPU, which performs computation in accordance with a control program, and storage media such as memory. The controller 7 controls the above-described components of the grinding apparatus 1 to perform grinding of the wafer 100.

The wafer processing method for processing the wafer 100 using the grinding apparatus 1 that is controlled by the controller 7 will be described below.

### [Positioning Process]

Firstly, a positioning process is performed. In this process, the controller 7 controls the robot 150 shown in FIG. 1 to unload an unprocessed wafer 100 from the first cassette 161 or the second cassette 163 to be held on the positioning table 60 of the positioning mechanism 6, thereby performing positioning of the wafer 100.

### [Holding Process]

After the positioning process, a holding process is performed. In this process, the wafer 100, which has undergone the positioning step, is held on the chuck table 5. Specifically, the controller 7 controls the loading mechanism 170 to hold the wafer 100 on the positioning table 60 and mounts the wafer 100 with the back surface 103 facing upwards on the holding surface 50 of the chuck table 5 arranged in the vicinity of the positioning mechanism 6. Afterward, the controller 7 communicates the holding surface 50 with the suction source (not shown in the figures). Accordingly, the holding surface 50 suction-holds the wafer 100.

### [Rough Grinding Process]

After the holding process, a rough grinding process is performed. The rough grinding process is an example of a processing process in which the wafer 100 is processed by a processing unit. In this process, the wafer 100, which is held on the chuck table 5, is roughly ground by the rough grinding mechanism 30 which functions as the processing unit. Specifically, after the holding process, the controller 7 rotates the turntable 2 to position the chuck table 5 holding the wafer 100 beneath the rough grinding mechanism 30. Furthermore, the controller 7 rotates the rough grinding stones 306 of the rough grinding mechanism 30 while simultaneously rotating the chuck table 5 that holds the wafer 100. Thereafter, the controller 7 uses the rough grinding feed mechanism 20 to lower the rough grinding mechanism 30 and to perform the rough grinding of the wafer 100. During this process, the controller 7 uses the first measurement mechanism 25 to measure the thickness of the wafer 100, which is being ground, and continues rough grinding until the thickness of the wafer 100 reaches the predetermined rough grinding thickness.

### [Finish Grinding Process]

After the rough grinding process, a finish grinding process is performed. This finish grinding process is another example of a processing process, in which the wafer 100 is processed by a processing unit. In this process, the finish grinding mechanism 31, which functions as the processing unit, performs the finish grinding on the wafer 100 held on the chuck table 5. Specifically, after the rough grinding process, the controller 7 rotates the turntable 2 to position the chuck table 5 holding the rough-ground wafer 100 beneath the finish grinding mechanism 31. Furthermore, the controller 7 rotates the finish grinding stones 310 of the finish grinding mechanism 31 while simultaneously rotating the chuck table 5 holding the wafer 100. Afterward, the controller 7 uses the finish grinding feed mechanism 21 to lower the finish grinding mechanism 31 to perform the finish grinding of the wafer 100. During this process, the controller 7 uses the second measurement mechanism 26 to measure the thickness of the wafer 100, which is being ground, and continues the finish grinding process until the thickness reaches a predetermined finish grinding thickness.

### [Cleaning Process]

After the finish grinding process, a cleaning process is performed. This cleaning process is a process to clean the processed wafer 100 that is held on the spinner table 80. In this process, the controller 7 controls the turntable 2 to rotate, causing the chuck table 5 holding the finished wafer 100 to position near the spinner cleaning mechanism 8 (near the positioning mechanism 6). Then, the controller 7 controls the loading mechanism 170 to hold the wafer 100 on the chuck table 5 and place the wafer 100 onto the holding surface 82 of the spinner table 80 of the spinner cleaning mechanism 8. Furthermore, the controller 7 opens the suction opening and closing valve 485 shown in FIG. 2, causing the holding surface 82 to communicate with the suction source 48. Accordingly, the holding surface 82 suction-holds the wafer 100.

Next, the controller 7 controls the rotation mechanism 85 to rotate the spinner table 80 while simultaneously injecting cleaning water from the nozzle 89 onto the wafer 100, thereby performing spinner cleaning of the wafer 100. Additionally, the controller 7 blows dry air from the nozzle 89 onto the wafer 100, thereby drying the wafer 100.

Afterward, the controller 7 controls the robot 150 shown in FIG. 1 to use the robot hand 151 to hold the wafer 100 on the spinner table 80 and to house the wafer 100 in the first cassette 161 or the second cassette 163 (the cassette from which the wafer 100 was unloaded).

In this embodiment, for example, the above-described holding process, rough grinding process, finish grinding process, and cleaning process are consecutively carried out on multiple wafers 100 (continuous processing).

Additionally, in the cleaning process, when the suction opening and closing valve 485 is opened to communicate the holding surface 82 with the suction source 48 for suction-holding the wafer 100 on the holding surface 82 of the spinner cleaning mechanism 8, for some reasons, the controller 7 may determine that the wafer 100 is not mounted on the holding surface 82.

That is, if the wafer 100 is not mounted on the holding surface 82, a large amount of air enters the suction pipe 481 from the holding surface 82, and consequently, the pressure value in the suction pipe 481, as measured by the pressure sensor 487 (the negative pressure value in the holding surface 82), does not fall no more than the predetermined threshold.

Therefore, if the measurement of the pressure sensor 487 does not fall no more than the predetermined threshold even after the holding surface 82 is communicated with the suction source 48, the controller 7 can determine that the wafer 100 is not mounted on the holding surface 82 of the spinner table 80. In this case, the controller 7 can, for example, temporarily halt the continuous processing.

As shown in FIG. 2, there may be a case where the wafer 100 mounted on the holding surface 82 of the spinner table 80 is damaged and a part of the wafer 100 is missing. In such a case, an exposed portion 821, which is a part of the holding surface 82 of the spinner table 80 not covered by the wafer 100, may occur. Also, if the wafer 100 mounted on the holding surface 82 has a large amount of warpage, it becomes difficult for the holding surface 82 to properly hold the entire surface of the wafer 100, and as a result, the exposed portion 821 may similarly occur on the holding surface 82.

Hence, similar to the case where the wafer 100 is not mounted on the holding surface 82, when a non-confirming wafer 100, which is difficult to be properly held by the holding surface 82, is mounted on the holding surface 82, a large amount of air enters the suction pipe 481 from the holding surface 82 when the suction opening and closing valve 485 is opened to communicate the holding surface 82 with the suction source 48. Accordingly, the suction pipe 481 measured by the pressure sensor 487 does not fall no more than the predetermined threshold, and as a result, continuous processing may be temporarily halted.

Furthermore, the non-confirming wafer 100 includes, for example, the wafer 100 with a missing part, the wafer 100 with warped outer edges, or the wafer 100 with cracks.

Accordingly, using only the measurement of the pressure sensor 487, it becomes difficult to distinguish between cases where the wafer 100 is not mounted on the holding surface 82 and cases where a non-confirming wafer 100 is mounted on the holding surface 82.

Therefore, in this embodiment, when the measurement of the pressure sensor 487 does not fall no more than the predetermined threshold and continuous processing is temporarily halted, the controller 7 performs a wafer detection process. In this process, the controller 7 controls to use the wafer presence sensor 153 of the robot hand 151 to detect whether the wafer 100 is present on the spinner table 80 before the cleaning process, specifically before transferring the wafer 100 to the spinner table 80 after the finish grinding, that is, before mounting the wafer 100 on the spinner table 80.

In particular, when the measurement of the pressure sensor 487 does not fall no more than the predetermined threshold, the controller 7, as shown in FIG. 2, after temporarily halting the continuous processing, controls the drive unit 154 of the robot 150 to position the suction surface 152 of the robot hand 151 above the holding surface 82 of the spinner table 80. Then, the controller 7 uses the wafer presence sensor 153 on the suction surface 152 of the robot hand 151 to detect the presence or absence of the wafer 100 on the holding surface 82.

At this time, for example, the controller 7 uses the wafer presence sensor 153 of the robot hand 151 to detect whether the wafer 100 is present on the spinner table 80 while relatively moving the spinner table 80 and the robot hand 151 positioned above the spinner table 80 in a horizontal direction.

For example, the controller 7 controls the rotation mechanism 85 of the spinner cleaning mechanism 8 to rotate the spinner table 80 at a low rotational speed while using the horizontal movement mechanism 156 of the drive unit 154 of the robot 150 to move the robot hand 151 horizontally. In this way, the wafer presence sensor 153 can detect the presence or absence of the wafer 100 across the entire surface of the holding surface 82.

Then, if the controller 7 determines, based on the wafer presence sensor 153, that there is no wafer 100 anywhere on the entire surface of the holding surface 82, the controller 7 concludes that the wafer 100 is not mounted on the holding surface 82 of the spinner table 80. In this case, the controller 7 can, for example, resume the continuous processing of the wafer 100 that had been temporarily halted. In other words, when the wafer 100 is detected to be absent from the spinner table 80 in the wafer detection process, the controller 7 resumes continuous processing and performs the cleaning process on the wafer 100 as using the spinner table 80 of the spinner cleaning mechanism 8 to hold the finish-ground wafer 100.

On the other hand, if the controller 7 determines, based on the wafer presence sensor 153, that there is the wafer 100 on an entire or a part of the holding surface 82, the controller 7 concludes that the non-confirming wafer 100, which is difficult to be held on the holding surface 82 properly, is mounted on the holding surface 82. In this case, the controller 7, for example, maintains the continuous processing of the wafer 100 halted and performs a notification process. In this process, the controller 7 uses the touch panel 9, which serves as a notification unit, to notify the operator that the un-confirming wafer 100 is mounted on the holding surface 82. In other words, if the controller 7 detects the presence of the wafer 100 on the spinner table 80 during the wafer detection process, the controller 7 performs the notification process via the touch panel 9 functioning as the notification unit to inform the operator that the wafer 100 is mounted on the spinner table 80.

It should be noted that, when the controller 7 determines that the wafer 100 is mounted on the entire surface of the holding surface 82 but if the wafer 100 is warped into either a convex shape or a concave shape in the middle, there may be a case where the measurement of the pressure sensor 487 does not fall no more than the predetermined threshold.

As described above, in this embodiment, when the measurement of the pressure sensor 487 does not fall no more than the predetermined threshold and continuous processing is temporarily halted, the wafer presence sensor 153 of the robot hand 151 detects the presence or absence of the wafer 100 on the holding surface 82. This enables clear detection of the presence or absence of the wafer 100 on the holding surface 82 of the spinner table 80.

Accordingly, for example, it becomes possible to effectively suppress situations where the non-confirming wafer 100 remains mounted on the holding surface 82 and continuous processing is resumed to superpose the next wafer 100 on the non-confirming wafer 100, causing damage to the wafers 100.

Additionally, there is no need for the operator to visually detect the presence or absence of the wafer 100 on the holding surface 82. This configuration improves work efficiency.

In this embodiment, the controller 7 performs the wafer detection process when the measurement of the pressure sensor 487 of the spinner cleaning mechanism 8 does not fall no more than the predetermined threshold and the continuous processing of the wafer 100, including the holding process, the processing process (the rough grinding process and the finish grinding process), and the cleaning process, is temporarily halted. Then, the controller 7 either resumes the wafer processing process to perform the cleaning process when no wafer 100 is detected on the spinner table 80 or performs the notification process when the wafer 100 is detected on the spinner table 80.

In this regard, the controller 7 can perform the wafer detection process at the predetermined timing set by the operator before the cleaning process. For example, the controller 7 may perform the wafer detection process when the continuous processing is temporarily halted due to the measurement of the pressure sensor 487 not falling no more than the predetermined threshold as described above, or may always or periodically temporarily halt the continuous processing and perform the wafer detection process, when performing the cleaning process on the wafer 100, before mounting the wafer 100 on the spinner table 80.

Additionally, in this embodiment, it is also possible to detect the presence of the wafer 100 on the positioning table 60 of the positioning mechanism 6 shown in FIG. 1.

Here, a configuration of the positioning table 60 will be described. As shown in FIG. 3, the positioning table 60 is a circular plate-like table for holding the wafer 100. The positioning table 60 has a circular plate-like table plate 61 and a table base 64 that supports the table plate 61. An upper surface of the table plate 61 is a holding surface 62 to suction-hold the wafer 100. The holding surface 62 has a linear suction groove 63 passing through a center thereof (see FIG. 1). The suction force from the suction source 48 is transmitted to the suction groove 63, allowing the positioning table 60 to suction-hold the wafer 100 on holding surface 62 of the table plate 61.

Additionally, the positioning table 60 is rotatable by a rotation mechanism 65. The rotation mechanism 65 has a configuration similar to the rotation mechanism 85 shown in FIG. 2 and includes a motor 66 as a driving source, a shaft 67 of the motor 66, and an encoder 68 that reads the rotational angle of the motor.

The shaft 67 is connected directly under the center of the holding surface 62 on the lower surface of the positioning table 60 (the table base 64) and extends vertically with respect to the holding surface 62 of the positioning table 60. As the motor 66 rotates the shaft 67, the positioning table 60 rotates around the center of the holding surface 62. Also, the encoder 68 can recognize the rotation angle of the positioning table 60 based on the rotational angle of the motor 66.

In addition, the positioning table 60 is connected to a fluid circulation mechanism 40a provided in the grinding apparatus 1. The fluid circulation mechanism 40a is a mechanism that supplies air to the holding surface 62 of the positioning table 60 or applies suction force to the holding surface 62.

Since the fluid circulation mechanism 40a has a configuration similar to the fluid circulation mechanism 40 shown in FIG. 2, a detailed description thereof is omitted. In this fluid circulation mechanism 40a, a table internal flow path 403 provided within the positioning table 60 is provided in the table plate 61 and the table base 64 of the positioning table 60, and an upper end of the table internal flow path 403 is connected to the suction groove 63 formed on the holding surface 62 of the table plate 61. Other components of the fluid circulation mechanism 40a are similar to those of the fluid circulation mechanism 40.

In other words, in the fluid circulation mechanism 40a, an air passage 470 extends from the table internal flow path 403 through the shaft 67 and rotary joint 460. The air supply source 47 or the suction source 48 is communicated with the suction groove 63 of the holding surface 62 through the air passage 470, the air pipe 471, and the suction pipe 481, supplying air to the holding surface 62 or applying suction force to the holding surface 62.

The pressure sensor 487 is provided in the suction pipe 481 in this configuration as well. Furthermore, when the suction opening and closing valve 485 is opened to communicate the suction groove 63 on the holding surface 62 with the suction source 48, if the pressure value in the suction pipe 481 measured by the pressure sensor 487 provided in the suction pipe 481 becomes no more than the predetermined threshold, it is determined that the wafer 100 is mounted on the holding surface 62 of the positioning table 60 and is held by the holding surface 62.

In this configuration, during the above-described holding process, when the suction opening and closing valve 485 is opened to communicate the suction groove 63 on the holding surface 62 with the suction source 48 in order to suction-hold the wafer 100 by the holding surface 62 of the positioning mechanism 6, there is a possibility that the wafer 100 may not be mounted on the holding surface 62 for some reasons. In this case, a large amount of air may enter the suction pipe 481 from the suction groove 63, so the pressure value in the suction pipe 481 (negative pressure value in the suction groove 63) measured by the pressure sensor 487 may not fall no more than the predetermined threshold.

Therefore, if the measurement of the pressure sensor 487 does not fall no more than the predetermined threshold even if the suction groove 63 is communicated with the suction source 48, the controller 7 can determine that the wafer 100 is not mounted on the holding surface 62 of the positioning table 60. In this case, for example, the controller 7 may temporarily halt the continuous processing.

As with the case of the spinner table 80 described above, if the wafer 100 mounted on the holding surface 62 of the positioning table 60 is damaged and a part of the wafer 100 is missing, an exposed portion 621 on the holding surface 62 (suction groove 63), which is not covered by the wafer 100, occurs. Similarly, if the wafer 100 mounted on the holding surface 62 has a large amount of warping, the exposed portion 621 on the holding surface 62 also occurs.

Thus, when the non-confirming wafer 100, which is difficult to hold properly on the holding surface 62, is mounted on the holding surface 62, similar to when no wafer 100 is mounted, the pressure value in the suction pipe 481 measured by the pressure sensor 487 does not fall no more than the predetermined threshold, and continuous processing may be temporarily halted.

In this embodiment, when the measurement of the pressure sensor 487 does not fall no more than the predetermined threshold and continuous processing is temporarily halted, the controller 7 performs the wafer detection process. In this process, the controller 7 controls to use the wafer presence sensor 153 of the robot hand 151 to detect whether the wafer 100 is present on the positioning table 60 before the positioning process, specifically, before transporting the wafer 100 housed in the first cassette 161 or the second cassette 163 to the positioning table 60, that is, before mounting the wafer 100 on the positioning table 60.

Specifically, when the measurement of the pressure sensor 487 does not fall no more than the predetermined threshold, the controller 7, after temporarily halting continuous processing, controls the drive unit 154 of the robot 150 to position the suction surface 152 of the robot hand 151 above the holding surface 62 of the positioning table 60. as shown in FIG. 3. Then, the controller 7 uses the wafer presence sensor 153 provided on the suction surface 152 of the robot hand 151 to detect the presence of the wafer 100 on the holding surface 62.

At this time, for example, the controller 7 uses the wafer presence sensor 153 of the robot hand 151 to detect whether the wafer 100 is present on the positioning table 60, while relatively moving the positioning table 60 and the robot hand 151 positioned above the positioning table 60 in a horizontal direction.

For example, the controller 7 controls the rotation mechanism 65 of the positioning mechanism 6 to rotate the positioning table 60 at a low rotational speed while using the horizontal movement mechanism 156 of the drive unit 154 of the robot 150 to move the robot hand 151 horizontally. This allows the wafer presence sensor 153 to detect the presence or absence of the wafer 100 across the entire surface of the holding surface 62.

Then, if the controller 7 determines that there is no wafer 100 anywhere on the entire surface of the holding surface 62, the controller 7 determines that the wafer 100 is not placed on the holding surface 62 of the positioning table 60. In this case, for example, the controller 7 resumes the temporarily halted continuous processing of the wafer 100. That is, if the wafer 100 is detected to be absent from the positioning table 60 during the wafer detection process, the controller 7 resumes continuous processing, and the wafer 100 is unloaded from the first cassette 161 or second cassette 163 to be mounted on the positioning table 60, performing the positioning process for that wafer 100.

On the other hand, if the controller 7 determines that there is the wafer 100 on the entire or a part of the holding surface 62, the controller 7 concludes that the non-confirming wafer 100, which is difficult to hold properly on the holding surface 62, is mounted on the holding surface 62. In this case, for example, the controller 7 performs the notification process while maintaining the suspension of continuous processing for the wafer 100. In this process, the controller 7 uses the touch panel 9, as the notification unit for sending information to the operator, to notify the operator that the non-confirming wafer 100 is mounted on the holding surface 62. That is, when the wafer 100 is detected to be present on the positioning table 60 during the wafer detection process, the controller 7 notifies the operator using the touch panel 9 that the wafer 100 is on the positioning table 60.

As such, with regard to the suction holding of the wafer 100 by the positioning table 60, when the continuous processing is temporarily halted due to the measurement of the pressure sensor 487 not falling no more than the predetermined threshold, the wafer presence sensor 153 of the robot hand 151 can detect the presence or absence of the wafer 100 on the holding surface 62; and therefore, it is possible to clearly detect the presence or absence of the wafer 100 on the holding surface 62 of the positioning table 60.

Accordingly, for example, this configuration can effectively suppress the damage of the wafer 100 caused when the continuous processing is resumed while the non-confirming wafer 100 remains placed on the holding surface 62 and an overlapping wafer 100 is superposed thereon.

Furthermore, it is not necessarily for the operator to visually check the presence or absence of the wafer 100 on the holding surface 62. This configuration improves work efficiency.

In the above embodiment, the controller 7 performs the wafer detection process when the measurement of the pressure sensor 487 of the positioning mechanism 6 does not fall no more than the predetermined threshold and the continuous processing of the wafer 100, which includes the holding process, the processing process (the rough grinding step and the finish grinding step), and the cleaning process, is temporarily halted. Then, the controller 7 resumes the wafer processing process and performs the positioning process when there is no wafer 100 on the positioning table 60, while performing the notification process when there is the wafer 100 on the positioning table 60.

In this regard, the controller 7 can perform the wafer detection process at the predetermined timing set by the operator before the positioning process. For example, the controller 7 may perform the wafer detection process when the continuous processing is temporarily halted due to the measurement of the pressure sensor 487 not falling no more than the predetermined threshold as described above, or may always or periodically temporarily halt the continuous processing and perform the wafer detection process, when performing the positioning process on the wafer 100, before mounting the wafer 100 on the positioning table 60.

In this embodiment, when detecting the presence or absence of the wafer 100 on the holding surface 82 (the holding surface 62) of the spinner table 80 (the positioning table 60) using the wafer presence sensor 153 of the robot hand 151, the spinner table 80 (the positioning table 60) and the robot hand 151 that is positioned above the spinner table 80 are relatively moved in a horizontal direction.

In this regard, it is also possible to detect the presence or absence of the wafer 100 by arranging the wafer presence sensor 153 of the robot hand 151 above the spinner table 80 (the positioning table 60) without performing such horizontal movement. However, by performing the above-described horizontal movement, the presence or absence of the wafer 100 can be more effectively detected.

Furthermore, regarding such horizontal movement, both the rotation of the spinner table 80 (the positioning table 60) and the horizontal movement of the robot hand 151 may be performed, or only one of the rotation of the spinner table 80 or the horizontal movement of the robot hand 151 may be performed.

Also, in this embodiment, the loading mechanism 170 and the unloading mechanism 172 are shown as a transport mechanism for unloading or loading the wafer 100 from or onto the chuck table 5. In this regard, the grinding apparatus 1 may not necessarily include the loading mechanism 170 and the unloading mechanism 172. In this case, for example, the robot 150 may be configured to transfer the wafer 100 to and from the chuck table 5. That is, in this case, the robot 150 may be configured to use the robot hand 151 to suction-hold the wafer 100, which is held on the positioning table 60, so as to be mounted on the holding surface 50 of the chuck table 5. Also, the robot 150 may be configured to use the robot hand 151 to suction-hold the finish ground wafer 100, which is held on the chuck table 5, so as to be mounted on the spinner table 80 of the spinner cleaning mechanism 8.

Furthermore, in this embodiment, the grinding apparatus 1 is illustrated as an example of the processing apparatus. In this regard, the processing apparatus in this embodiment may include other processing apparatus such as a polishing apparatus for polishing the wafer 100 and a cutting apparatus for dividing the wafer 100 into chips as long as the apparatus includes a table for suction-holding the wafer 100 and the robot 150.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A processing apparatus, comprising:
a cassette stage for mounting a cassette thereon;
a chuck table to suction-hold a wafer;
a processing unit to process the wafer that is held on the chuck table;
a processing table that is used to perform a predetermined processing on a wafer;
a robot equipped with a robot hand that has a wafer presence sensor to detect a presence or absence of a wafer and holds a wafer to unload or load the wafer from or into the cassette mounted on the cassette stage; and
a controller that uses the wafer presence sensor of the robot hand to detect whether a wafer is present on the processing table.

2. The processing apparatus according to claim 1, wherein the processing table is a spinner table that suction-holds a wafer to perform a cleaning process on the wafer.

3. The processing apparatus according to claim 2,
wherein the controller uses the wafer presence sensor of the robot hand to detect the presence or absence of a wafer on the spinner table while relatively moving the spinner table and the robot hand, which is positioned above the spinner table, in a horizontal direction.

4. The processing apparatus according to claim 2,
further comprising a pressure sensor that measures a pressure value in a suction pipe connecting the spinner table and a suction source,
wherein the controller uses the wafer presence sensor of the robot hand to detect the presence or absence of a wafer on the spinner table if the measurement of the pressure sensor does not fall no more than a predetermined threshold when the spinner table suction-holds a wafer.

5. The processing apparatus according to claim 1,
wherein the processing table is a positioning table for positioning a wafer to be held on the chuck table.

6. The processing apparatus according to claim 5,
wherein the controller uses the wafer presence sensor of the robot hand to detect the presence or absence of a wafer on the positioning table while relatively moving the positioning table and the robot hand, which is positioned above the positioning table in a horizontal direction.

7. The processing apparatus according to claim 5,
further comprising a pressure sensor that measures a pressure value in a suction pipe connecting the positioning table and a suction source,
wherein the controller uses the wafer presence sensor of the robot hand to detect the presence or absence of a wafer on the positioning table if the measurement of the pressure sensor does not fall no more than a predetermined threshold when the positioning table suction-holds a wafer.

8. A wafer processing method using the processing apparatus according to claim 2, comprising:
holding a wafer on the chuck table;
processing the wafer with the processing unit;
holding the processed wafer on the spinner table and cleaning the wafer; and
detecting the presence or absence of a wafer on the spinner table using the wafer presence sensor of the robot hand at a predetermined timing before the cleaning of the wafer,
wherein during the detection of the presence or absence of a wafer on the spinner table, if a wafer is detected to be absent from the spinner table, cleaning of the wafer is performed, while during the detection of the presence or absence of a wafer, if a wafer is detected to be present on the spinner table, a notification unit of the processing apparatus notifies an operator that a wafer is present on the spinner table.

9. A wafer processing method using the processing apparatus according to claim 5, comprising:
unloading a wafer from the cassette and holding the wafer on the positioning table to perform positioning of the wafer;
holding the positioned wafer on the chuck table;
processing the wafer with the processing unit; and
detecting the presence or absence of a wafer on the positioning table using the wafer presence sensor of the robot hand at a predetermined timing before the positioning of the wafer,
wherein during the detection of the presence or absence of a wafer on the positioning table, if a wafer is detected to be absent from the positioning table, positioning of the wafer is performed, while during the detection of the presence or absence of a wafer, if a wafer is detected to be present on the positioning table, a notification unit of the processing apparatus notifies an operator that a wafer is present on the positioning table.
